(19) United States
(12) Patent Application Publication
(10) Pub. No.: US 2012/0025675 A1
(43) Pub. Date: Feb. 2, 2012

(54) PIEZOELECTRIC VIBRATOR ELEMENT AND METHOD OF MANUFACTURING THE SAME

(75) Inventor: Ryoichi YASUIKE, Minamisoma-shi (JP)

(73) Assignee: SEIKO EPSON CORPORATION, TOKYO (JP)

(21) Appl. No.: 13/096,485

(22) Filed: Apr. 28, 2011

(30) Foreign Application Priority Data
Jul. 28, 2010 (JP) 2010-169010

(51) Int. Cl. H01L 41/04; H01L 41/22

(52) U.S. Cl. 310/367; 29/25.35

(57) ABSTRACT

A piezoelectric vibrator element provided by performing wet etching on a piezoelectric substrate includes: a thin-wall section including a vibrating section; a thick-wall section thicker than the thin-wall section; and a slit section penetrating in a thickness direction, wherein the slit section is disposed in an area intervening between the thin-wall section and the thick-wall section.

### BACKGROUND

1. Technical Field

The present invention relates to a piezoelectric vibrator element and a manufacturing method thereof, and in particular to an inverted-mesa piezoelectric vibrator element provided with a slit section and a manufacturing method thereof.

2. Related Art

In the past, as a mounting form of the piezoelectric vibrator element, there can be cited a form of applying an electrically conductive adhesive to thereby fixing the piezoelectric vibrator element to a package. If the piezoelectric vibrator element is thus supported by the electrically conductive adhesive, there arises a problem that the distortion due to the difference in linear expansion coefficient between the piezoelectric vibrator element, the package, and the electrically conductive adhesive remains in the fixing section in the reflow process for curing the electrically conductive adhesive, and the stress from the fixing section to the vibrating section exerts a harmful influence on the vibration. In order for avoiding this problem, it has been performed to provide a slit between the portion coated with the electrically conductive adhesive and the vibrating section (see, e.g., JP-A-2009-158999 and JP-A-2002-246869).

Further, in order for assuring the strength, it has been performed that a recess is formed at the central portion of the piezoelectric vibrator element to be changed to an inverted-mesa type (see, e.g., the documents mentioned above). In recent years, further miniaturization of the inverted-mesa piezoelectric vibrator element has been requested. Wet etching, which has high productivity, is often adopted for forming the shape of the inverted-mesa piezoelectric vibrator element. However, when forming the piezoelectric vibrator element from a quartz crystal, the manufacture of the quartz crystal using the wet etching is affected by the crystal orientation of the quartz crystal. Specifically, the etching rate is different between the crystal plane appearing on the etching surface, and the tilted surface (the crystal plane) called residual dross appears in the area intervening between the thin-wall section provided with the inverted mesa and the thick-wall section surrounding the thin-wall section. For example, in the case of performing the wet etching from the +Y″-axis principal surface on an AT-cut quartz crystal substrate, a relatively large residual dross occurs in the area at portions respectively shifted in the −Z′ direction and the +X direction of the crystal axis of the quartz crystal. The residual dross problematically affects the vibration characteristics. According to JP-A-2009-164824, the cutting angle and the vibration area of the quartz crystal vibrator element is designed optimally, and the portion where the residual dross occurs is removed by etching.

In the case of providing the slit between the fixing portion of the inverted-mesa quartz crystal vibrator element and the vibrating section thereof in order for preventing the stress from the portion where the quartz crystal vibrator element is fixed to the package from propagating to the vibrating section, it is required to prepare the area where the slit section is formed and the area where the residual dross to be removed is formed when forming the outer shape of the quartz crystal vibrator element. The area for the residual dross to be removed forms a large wasteful area. Therefore, there arises a problem that it is not achievable to miniaturize the quartz crystal vibrator element, and it is not achievable to assure the sufficient number of quartz crystal vibrator elements obtained from one wafer. Further, the process for removing the residual dross is required for eliminating the influence of the residual dross, which becomes a factor for degrading the productivity.

### SUMMARY

An advantage of some aspects of the invention is to provide an inverted-mesa piezoelectric vibrator element having a slit, which is small in size and has little residual dross, and a method of manufacturing the piezoelectric vibrator element.

Another advantage of some aspects of the invention is to provide a method of manufacturing the piezoelectric vibrator element with high productivity.

### Application Example 1

According to this application example of the invention, there is provided a piezoelectric vibrator element provided by performing wet etching on a piezoelectric substrate, including a thin-wall section including a vibrating section, a thick-wall section thicker than the thin-wall section, and a slit section penetrating in a thickness direction, wherein the slit section is disposed in an area intervening between the thin-wall section and the thick-wall section.

According to this application example of the invention, since the area where the residual dross occurs and the area where the slit section is disposed, which have been disposed separately, can be the same area by disposing the slit section in the area intervening between the thin-wall section and the thick-wall section, the piezoelectric vibrator element can be miniaturized.

Further, since the area where the residual dross occurs is changed to the slit section, it becomes possible to reduce the residual dross to thereby improve the frequency characteristics.

### Application Example 2

According to this application example of the invention, in the piezoelectric vibrator element according to the application example 1 of the invention, at least a part of the thick-wall section is provided with a connection electrode to be connected to an electrode provided to a package, the thin-wall section is provided with an excitation electrode electrically connected to the connection electrode, and the slit section is disposed in the area, which intervenes between the thin-wall section and the thick-wall section, and is sandwiched between the connection electrode and the excitation electrode.

According to this application example of the invention, the stress from the thick-wall section provided with the connection electrodes to be connected to the electrodes provided to the package can be prevented from propagating to the thin-wall section provided with the excitation electrode.

### Application Example 3

According to this application example of the invention, in the piezoelectric vibrator element according to the application example 2 of the invention, portions of the thick-wall section adjacent to both sides of the thin-wall section are each provided with the connection electrode, and the slit section is disposed in an area intervening between each of the thick-wall sections provided with the connection electrode and the thin-wall section.

According to this application example of the invention, since the connection electrode is disposed in the thick-wall section adjacent to the both end sides of the thin-wall section of the piezoelectric vibrator element, the both sides of the piezoelectric vibrator element can be fixed to the package, and thus, the impact resistance of the piezoelectric vibrator element can be improved. Further, the slit section is disposed in the area intervening between each of the thick-wall sections provided with the connection electrodes and the thin-wall section, it is possible to prevent the stress from the thick-wall section provided with the connection electrode to be connected to the package from propagating to the thin-wall section provided with the excitation electrode.

### Application Example 4

According to this application example of the invention, in the piezoelectric vibrator element according to the application example 1 or 2 of the invention, the piezoelectric substrate is an AT-cut substrate, the piezoelectric substrate has edges respectively parallel to a Z″-axis obtained by rotating a Z′-axis in the piezoelectric substrate around a Y′-axis, and an X′-axis perpendicular to the Z″-axis, and the slit section is disposed on one end side of the Z″-axis direction.

According to this application example of the invention, since the slit section can be disposed in the area intervening between the thick-wall section on one end side in the Z″-axis direction and the thin-wall where the residual dross appears significantly, the residual dross of the piezoelectric vibrator element can be reduced.

### Application Example 5

According to this application example of the invention, in the piezoelectric vibrator element according to any of the application examples 1 to 3 of the invention, the piezoelectric substrate is an AT-cut substrate, the piezoelectric substrate has edges respectively parallel to a Z″-axis obtained by rotating a Z′-axis in the piezoelectric substrate around a Y′-axis, and an X′-axis perpendicular to the Z″-axis, and a plural number of the slit sections are disposed along the Z″-axis.

According to this application example of the invention, the thick-wall section adjacent to each of the plurality of slit sections can be fixed to the package, thus the impact resistance can be improved.

### Application Example 6

According to this application example of the invention, in the piezoelectric vibrator element according to any of the application examples 1 to 5 of the invention, the piezoelectric substrate is an AT-cut substrate, the piezoelectric substrate has edges respectively parallel to a Z″-axis obtained by rotating a Z′-axis in the piezoelectric substrate around a Y′-axis, and an X′-axis perpendicular to the Z″-axis, and the slit section is disposed in parallel to the Z″-axis.

According to this application example of the invention, by disposing the slit section in the area intervening between the thick-wall section parallel to the Z″-axis and the thin-wall section, the residual dross appearing in the area intervening between the thick-wall section and the thin-wall section can further be reduced.

### Application Example 7

According to this application example of the invention, in the piezoelectric vibrator element according to any of the application examples 1 to 6 of the invention, assuming that an angle of rotation of a +Z′-axis around a Y′-axis toward the +X-axis direction corresponds to a positive rotational angle in the piezoelectric substrate, the piezoelectric substrate has edges respectively parallel to a Z″-axis obtained by rotating a Z′-axis around a Y′-axis in a range from −120° to +60°, and an X′-axis perpendicular to the Z″-axis, and the thin-wall section is formed by wet etching from either one of a +Y′-axis side principal surface and a −Y′-axis side principal surface, and is provided with the slit section disposed at least in the area at a position shifted toward a −Z″ direction if the wet etching is performed from the +Y′-axis side principal surface, and is provided with the slit section disposed at least in the area at a position shifted toward a +Z″ direction if the wet etching is performed from the −Y′-axis side principal surface.

According to this application example of the invention, the penetrating slit can be disposed in at least the area with the largest residual dross, and thus, the residual dross can be reduced.

### Application Example 8

According to this application example of the invention, in the piezoelectric vibrator element according to the application example 7 of the invention, the range of the rotational angle of the Z′-axis is set to a range from −60° to −25°, and the slit sections are disposed at least in the area at positions respectively shifted toward the −Z″ direction and the −X′ direction if the wet etching is performed from the +Y′-axis side principal surface, and the slit sections are disposed at least in the area at positions respectively shifted toward the +Z″ direction and the +X′ direction if the wet etching is performed from the −Y′-axis side principal surface.

According to this application example of the invention, the slit section can be disposed in the area where the residual dross appears significantly, and the residual dross can be reduced.

### Application Example 9

According to this application example of the invention, in the piezoelectric vibrator element according to any of the application examples 1 to 8 of the invention, the slit section is formed by cutting a side surface.

According to this application example of the invention, since the portion connecting the thick-wall section and the thin-wall section is reduced, it is possible to make the stress from the thick-wall section difficult to propagate to the thin-wall section.

### Application Example 10

According to this application example of the invention, there is provided a method of manufacturing a piezoelectric vibrator element having a thin-wall section including a vibrating section, a thick-wall section thicker than the thin-wall section, and a slit section penetrating in a thickness direction including: forming an inverted-mesa shape by forming the thin-wall section and the thick-wall section by wet etching to one of principal surfaces of a piezoelectric substrate, and forming the slit section in an area intervening between the thin-wall section and the thick-wall section.

According to this application example of the invention, by forming the slit section in the area intervening between the thin-wall section and the thick-wall section, the residual dross can be reduced, and the frequency characteristics can be improved. Further, by making the area where the residual dross appears and the area where the slit section is disposed the same area, it becomes unnecessary to prepare both of the area where the slit section is formed and the area of the residual dross to be removed in the outer shape formation process, the piezoelectric vibrator element can be miniaturized, and therefore, the number of pieces can be obtained from one wafer can be increased. Further, since the process for removing the residual dross can be reduced, the productivity can be improved.

### Application Example 11

According to this application example of the invention, in the method of manufacturing a piezoelectric vibrator element according to the application example 10 of the invention, the slit section is formed at least in an area with a tilt surface having a largest tilt angle out of an area intervening between the thin-wall section and the thick-wall section.

According to this application example of the invention, the largest residual dross can be eliminated, and the frequency characteristics can be improved.

### Application Example 12

According to this application example of the invention, in the method of manufacturing a piezoelectric vibrator element according to the application example 10 or 11 of the invention, wet etching is performed on both principal surfaces of the piezoelectric substrate in a condition in which masks corresponding to an outer shape of the slit section are disposed so as to be shifted from each other in a principal surface direction of the piezoelectric substrate.

By adopting the configuration described above, it is possible to prevent the protrusion due to the etching anisotropy from appearing in the slit section.

### BRIEF DESCRIPTION OF THE DRAWINGS

The invention will be described with reference to the accompanying drawings, wherein like numbers reference like elements.

FIG. 1A is a plan view of a quartz crystal vibrator element according to the present embodiment viewed from above, FIG. 1B is a cross-sectional view of the quartz crystal vibrator element shown in FIG. 1A along the line A-A, and FIG. 1C is a cross-sectional view of the quartz crystal vibrator element shown in FIG. 1A along the line B-B.

FIG. 2 is a diagram for explaining the rotational angle of a quartz crystal substrate.

FIG. 3A is a plan view of a quartz crystal vibrator element according to a modified example viewed from below, FIG. 3B is a cross-sectional view of the quartz crystal vibrator element shown in FIG. 3A along the line A′-A′, and FIG. 3C is a cross-sectional view of the quartz crystal vibrator element shown in FIG. 3A along the line B′-B′.

FIG. 4A is a plan view of a quartz crystal vibrator element according to another modified example viewed from below, FIG. 4B is a cross-sectional view of the quartz crystal vibrator element shown in FIG. 4A along the line A″-A″, and FIG. 4C is a cross-sectional view of the quartz crystal vibrator element shown in FIG. 4A along the line B″-B″.

FIG. 5 is an explanatory diagram of a formation process of an outer shape in the manufacturing method of the quartz crystal vibrator element in which a thin-wall section is formed after forming the outer shape.

FIG. 6 is an explanatory diagram of a formation process of an inverted mesa in the manufacturing method of the quartz crystal vibrator element in which the thin-wall section is formed after forming the outer shape.

FIG. 7 is an explanatory diagram of an electrode formation process in the manufacturing method of the quartz crystal vibrator element in which the thin-wall section is formed after forming the outer shape.

FIG. 8 is an explanatory diagram of a formation process of an inverted mesa in the manufacturing method of the quartz crystal vibrator element in which the outer shape is formed after forming the thin-wall section.

FIG. 9 is an explanatory diagram of a formation process of an outer shape in the manufacturing method of the quartz crystal vibrator element in which the outer shape is formed after forming the thin-wall section.

FIG. 10 is a diagram showing a modified example of a position where the slit section is formed.

FIG. 11 is a diagram showing another modified example of a position where the slit section is formed.

FIG. 12 is a diagram showing a modified example of a shape of the slit section.

FIG. 13A is a schematic diagram showing the positional relationship between an electrically conductive adhesive and the quartz crystal vibrator element viewed from below in the condition in which the quartz crystal vibrator element does not yet have contact with the electrically conductive adhesive to be fixed to the package in the case in which a plurality of grooves is provided to the portion of the quartz crystal vibrator element to be coated with the electrically conductive adhesive,

FIG. 13B is a schematic diagram showing the condition of extension of the electrically conductive adhesive in the horizontal direction when the quartz crystal vibrator element and the package are fixed to each other with the electrically conductive adhesive, and

FIG. 13C is a schematic cross-sectional view of the quartz crystal vibrator element shown in FIG. 13B along the line C-C.

### DESCRIPTION OF AN EXEMPLARY EMBODIMENT

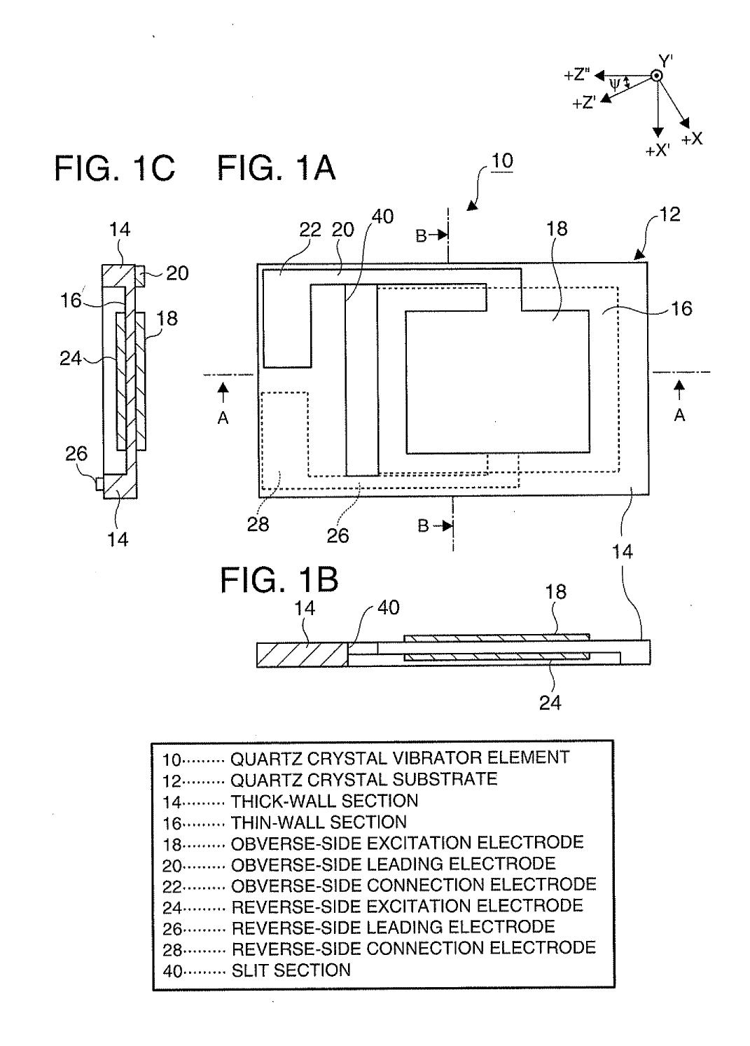

An embodiment of the invention will hereinafter be described in detail with reference to the accompanying drawings. FIG. 1A is a plan view of a quartz crystal vibrator element 10 viewed from the above, FIG. 1B is a cross-sectional view of the quartz crystal vibrator element 10 shown in FIG. 1A along the line A-A, and FIG. 1C is a cross-sectional view of the quartz crystal vibrator element 10 shown in FIG. 1A along the line B-B.

The quartz crystal vibrator element 10 is composed of a quartz crystal substrate 12, and electrode patterns 18, 20, 22, 24, 26, and 28 formed on the surface of the quartz crystal substrate 12.

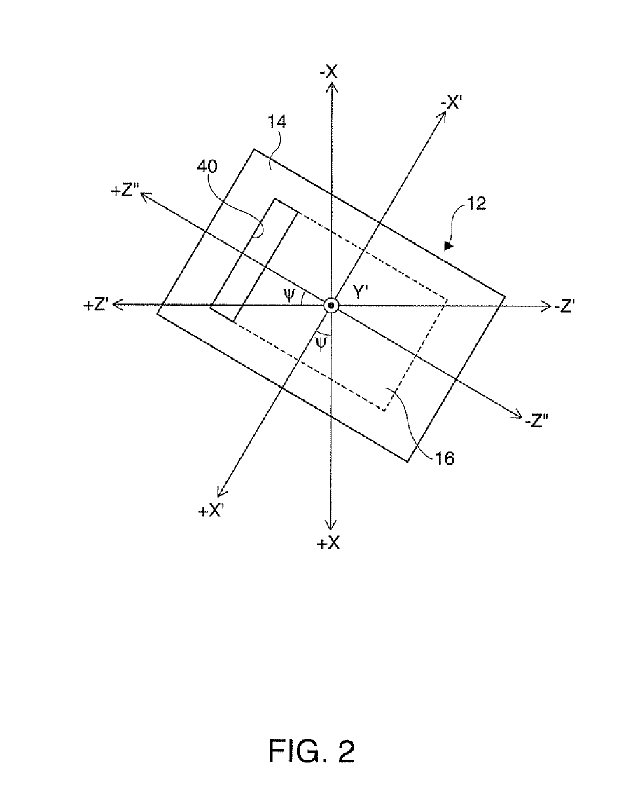

As the quartz crystal substrate 12 according to the present embodiment, the substrate obtained by performing so-called in-plane rotation on an AT-cut quartz crystal substrate is used. In a more detailed explanation, the AT-cut quartz crystal substrate denotes the quartz crystal substrate carved out so as to include a principal surface (a principal surface including the X-axis and the Z′-axis) obtained by rotating the plane (the Y-plane) including the X-axis and the Z-axis as the crystal axes of the quartz crystal so that the +Z-axis is rotated around the X-axis approximately 35° 15′ toward the −Y-axis direction (counterclockwise). Further, as shown in FIG. 2, the quartz crystal substrate 12 according to the present embodiment has edge sides along (parallel to) the X′-axis and the Z″-axis obtained by rotating each of the X-axis and the Z′-axis approximately ψ(−30°±5° assuming that the angle of the rotation of the +Z′-axis around the Y′-axis of the AT-cut quartz crystal substrate toward the +X-axis direction corresponds to a positive rotational angle (it should be noted that in the present specification, the axis extending from the origin toward the +I (I=X, Y, Z) direction is denoted as +I-axis, and the axis extending from the origin toward the −I direction is denoted as −I-axis, and further, in the case in which the +I axis and the −I axis are not particularly distinguished, they are both denoted simply as I-axis).

As shown in FIG. 2, in the present embodiment, the explanation will be presented assuming that the longitudinal direction of the quartz crystal substrate 12 is a Z″-axis, the direction along the shorter side is an X′-axis, the thickness direction is a Y′-direction, and the front side of the sheet is the +Y′ direction.

The quartz crystal substrate 12 has a thin-wall section 16 including the vibrating section, and a thick-wall section 14 adjacent to the periphery thereof. The thin-wall section 16 is formed to have an inverted-mesa shape by the wet etching from the −Y′-axis side principal surface.

In the case of processing the quartz crystal substrate 12 by the wet etching using the etching liquid such as hydrofluoric acid, the difference in etching rate by precipitation of the crystal plane might occur due to the anisotropic nature of the crystal orientation of the quartz crystal. In particular, in the quartz crystal substrate carved out with a cutting angle called AT-cut, existence of the residual dross (the tilted surface) appearing on the processed surface by the wet etching is often regarded as a problem. The amount of the residual dross on the processed surface varies by factors of various types of carved-out angles such as the cutting angle or the in-plane rotational angle.

For example, in the case of forming the inverted-mesa from the typical AT-cut quartz crystal substrate by performing the wet etching from the +Y′-axis side principal surface, relatively large residual dross appears in the area intervening between the thick-wall section 14 and the thin-wall section 16 shifted toward the −Z′ direction and the +X direction. On the other hand, in the case of forming the inverted-mesa from the quartz crystal substrate 12 carved out at the in-plane rotational angle ψ described above adopted in the present embodiment by performing the wet etching from the −Y′-axis side principal surface, the residual dross significantly appears on one side shifted toward the +Z″ direction.

Therefore, the quartz crystal substrate 12 according to the present embodiment is provided with the slit section 40 formed in the area on the side (shifted toward the +Z″ direction) where the residual dross appears out of the area intervening between the thin-wall section 16 and the thick-wall section 14. Since it is possible to make the area where the residual dross appears and the area of the slit section 40 identical to each other by thus providing the slit section 40 in the area where the residual dross appears, the necessity of separately preparing the area where the residual dross appears and the area of the slit section 40 is eliminated, and the quartz crystal vibrator element 10 can be miniaturized. Further, since the residual dross can be reduced, the frequency characteristics can be improved.

The quartz crystal substrate 12 having such an outer shape is provided with electrode patterns such as an obverse-side excitation electrode 18, a reverse-side excitation electrode 24, an obverse-side connection electrode 22, a reverse-side connection electrode 28, an obverse-side leading electrode 20, and a reverse-side leading electrode 26 as shown in FIGS. 1A through 1C.

In detail, the obverse-side excitation electrode and the reverse-side excitation electrode 24 are disposed respectively at the center portions of the upper and lower surfaces of the thin-wall section 16 so as to be opposed to each other to thereby provide the vibrating section to the thin-wall section 16. The obverse-side leading electrode 20 is drawn from the obverse-side excitation electrode 18 to the −X′ direction edge, then drawn to the +Z″ direction end along the −X′ direction edge, and then connected to the obverse-side connection electrode 22. The reverse-side leading electrode 26 is drawn from the reverse-side excitation electrode 24 to the +X′ direction edge, then drawn to the +Z″ direction end along the +X′ direction edge, and then connected to the reverse-side connection electrode 28.

The thick-wall section 14 in the +Z″ direction end, which is provided with the obverse-side connection electrode 22 and the reverse-side connection electrode 28, is fixed to the package for housing the quartz crystal vibrator element 10 with an electrically conductive adhesive, bonding wires, bumps, and so on. By providing the slit section 40 between the thick-wall section 14 to be fixed to the package and the thin-wall section 16 adjacent thereto, it becomes possible to prevent the stress from propagating from the thick-wall section 14 to the thin-wall section 16, and thus, it becomes possible to stabilize various characteristics.

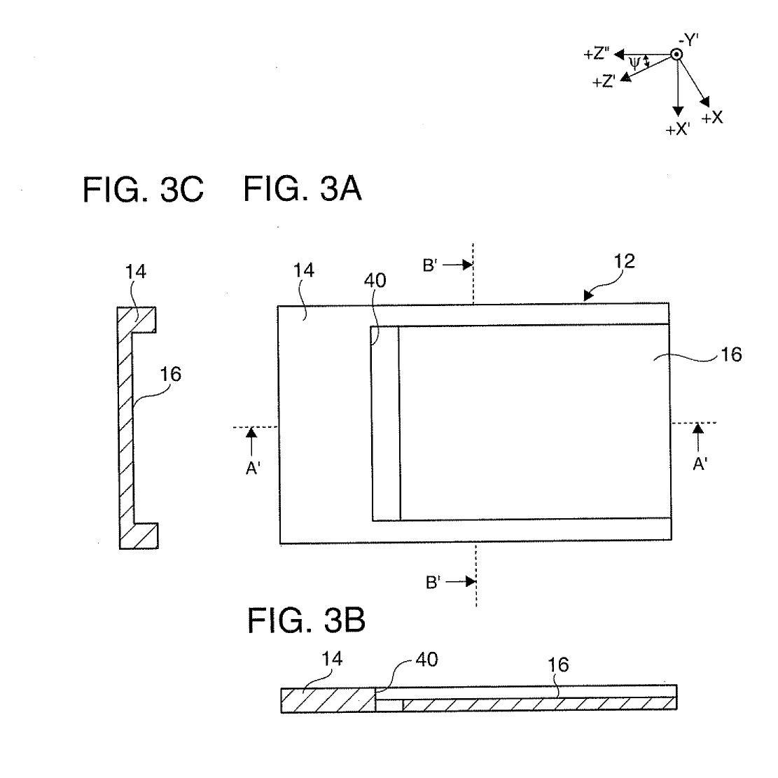

It should be noted that although in the example described above the configuration of disposing the thick-wall section 14 so as to be adjacent to the entire circumference of the thin-wall section 16 is adopted, this is not a limitation. For example, it is also possible to form the −Z″ direction end of the quartz crystal substrate 12 as a part of the thin-wall section, thereby forming the thick-wall section 14 to have a roughly U shape along the edges other than the −Z″ direction edge as shown in FIGS. 3A through 3C. By forming the thick-wall section 14 as described above, the weight of the −Z″ direction end located on the opposite side to the +Z″ direction end to be the fixed end is reduced, and therefore, the impact applied to the thick-wall section 14 and the slit section 40 is reduced, and thus, it becomes possible to improve the impact resistance.

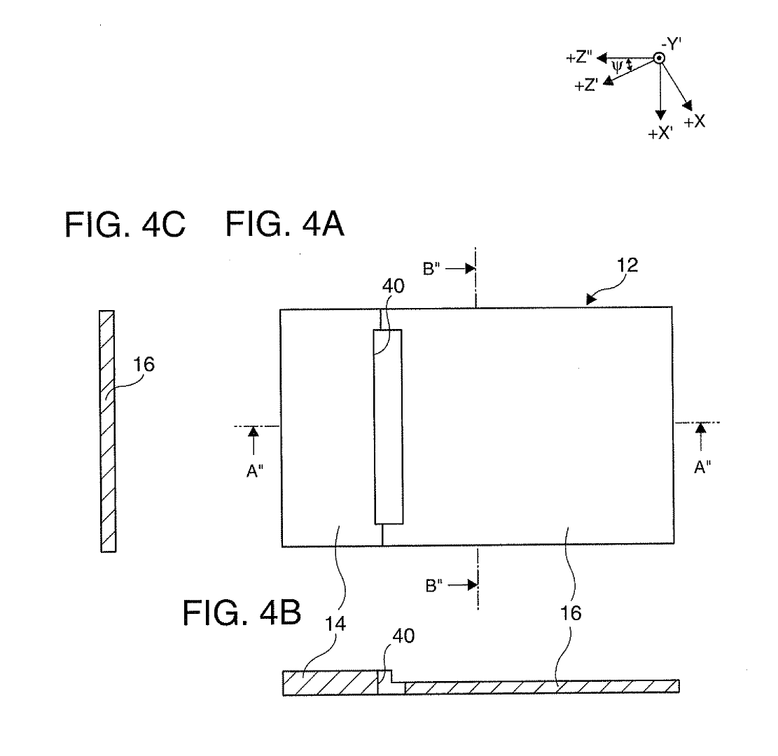

Further, as another form, as shown in FIGS. 4A through 4C, it is also possible to limit the area provided with the thick-wall section 14 to the +Z″ direction end of the quartz crystal substrate 12, and to make the other three sides thin-wall. On this occasion, since the weight is further reduced, the impact applied to the thick-wall section 14 and the slit section 40 can further be reduced.

Then, a method of manufacturing the quartz crystal vibrator element described above will be explained. Here, the manufacturing method of the quartz crystal vibrator element having the −Z″ direction end made thin-wall shown in FIGS. 3A through 3C will be explained. The quartz crystal vibrator element is manufactured in a batch process of forming a plurality of outer shapes on one wafer. Hereinafter, the explanation will be presented using the schematic cross-sectional view of a partial wafer (hereinafter referred to as a quartz crystal substrate 30) to be provided with one quartz crystal vibrator element out of one wafer.

Here, as the method of manufacturing the quartz crystal vibrator element, it is possible to cite a first manufacturing method in which the thin-wall section (the inverted mesa) is formed after forming the outer shape of the quartz crystal vibrator element, and a second manufacturing method in which the outer shape is formed after forming the thin-wall section.

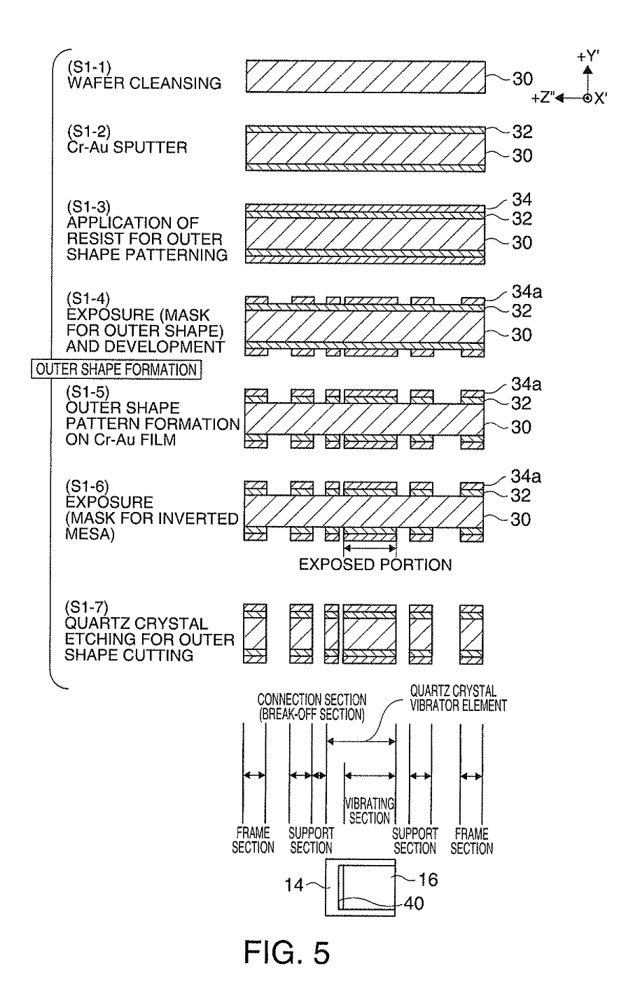

Hereinafter, the first manufacturing method of forming the thin-wall section after forming the outer shape will be explained with reference to FIGS. 5 through 7.

Firstly, an outer shape formation process shown in FIG. 5 is performed.

In the outer shape formation process, firstly the quartz crystal substrate 30 cut out in the AT-cut manner is cleaned (S1-1), then a Cr film and an Au film (hereinafter referred to as a “Cr—Au film”) 32 are formed on the both principal surfaces thereof by sputtering (S1-2). Then, a photoresist 34 for outer-shape patterning is applied (S1-3) to the both principal surfaces of the quartz crystal substrate 30.

The photoresist 34 is exposed using a photo mask for the outer shape formation, and then the exposed portions are removed by the development, thereby forming (S1-4) the photoresist (referred to as a “resist mask 34a”) provided with the outer-shape pattern of the quartz crystal. On this occasion, the outer shape of the quartz crystal vibrator element is formed so that the edges thereof are parallel to the Z″-axis and the X′-axis, respectively. Further, the outer shape of the slit section is formed in the area shifted toward the Z″ direction in the area intervening between the thin-wall section and the thick-wall section to be formed in the thin-wall section (the inverted mesa) formation process to be performed later.

Further, the resist masks 34a corresponding to the slit section 40 are formed so that the mask positions of the respective principal surfaces are different with respect to the thickness direction (a vertical direction) of the quartz crystal substrate 30, and shifted from each other in the principal surface direction (a horizontal direction). The direction in which the resist masks 34a are shifted from each other is preferably the Z′ direction, and the shift amount is preferably set to the range from a half of the quartz crystal substrate 30 to the same level thereof. If the positions of the resist masks 34a are not shifted from each other, when forming the slit section by wet etching, the protrusions tilted at angles with the AT-cut surface different from each other appear due to the etching anisotropy of the quartz crystal. However, by thus shifting the masks, it is possible to prevent the protrusions from being formed on the surface of the slit section.

Subsequently, by etching the Cr—Au films 32 exposed from the resist masks 34a using the resist masks 34a as the protective films, the outer shape pattern is provided to the Cr—Au films 32 (S1-5).

Subsequently, the resist masks 34a corresponding to the portion where the thin-wall section (the inverted mesa) is formed is exposed (S1-6) using the photo masks for forming the inverted mesa.

Then, the wet etching is performed on the quartz crystal substrate 30 from the both principal surface sides, thereby vertically penetrating (S1-7) the portion, which is not protected by the resist mask 34a. On this occasion, since the positions of the resist masks 34a corresponding to the slit section are shifted from each other, it is possible to prevent the projections from appearing on the surface of the slit section.

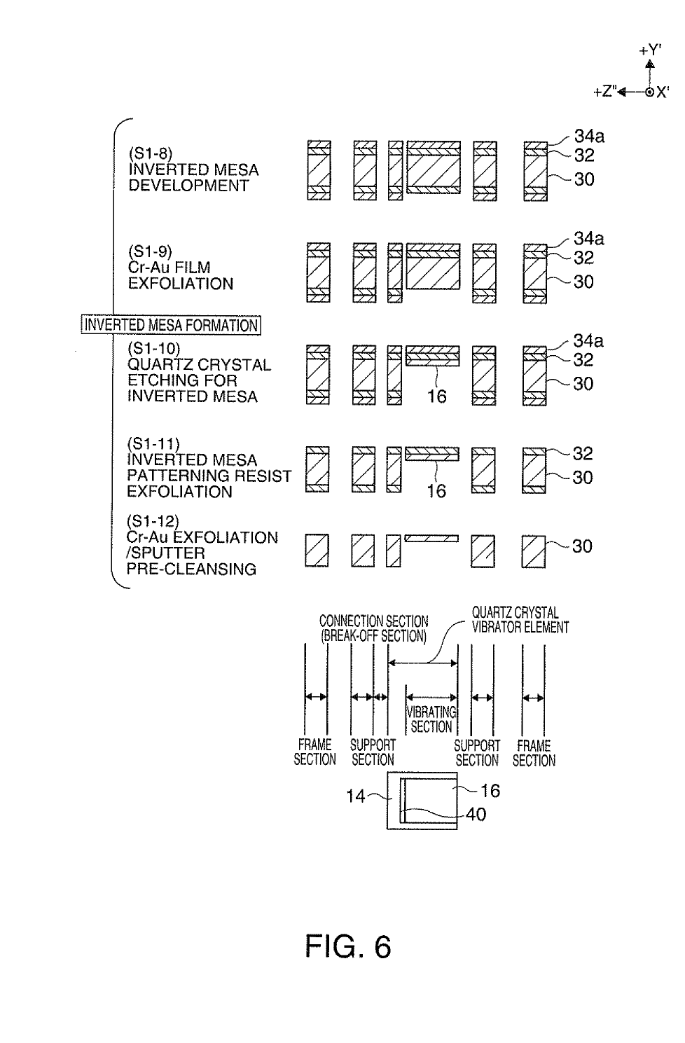

Subsequently, the process of forming the thin-wall section (the inverted mesa) shown in FIG. 6 is performed.

In this process, firstly, the development of the resist mask 34a is performed to thereby remove (S1-8) the portion exposed in the step S1-6. Then the Cr—Au films 32 exposed by removing the exposed portions are exfoliated (S1-9) using the resist masks 34a as the protective films.

Subsequently, the wet etching on the portion of the quartz crystal substrate 30 exposed by the exfoliation of the Cr—Au films 32 is performed to thereby form (S1-10) the thin-wall section 16 (inverted mesa).

Subsequently, after exfoliating the entire resist masks 34a (S1-11), the entire Cr—Au films 32 are exfoliated, and the cleansing is performed (51-12).

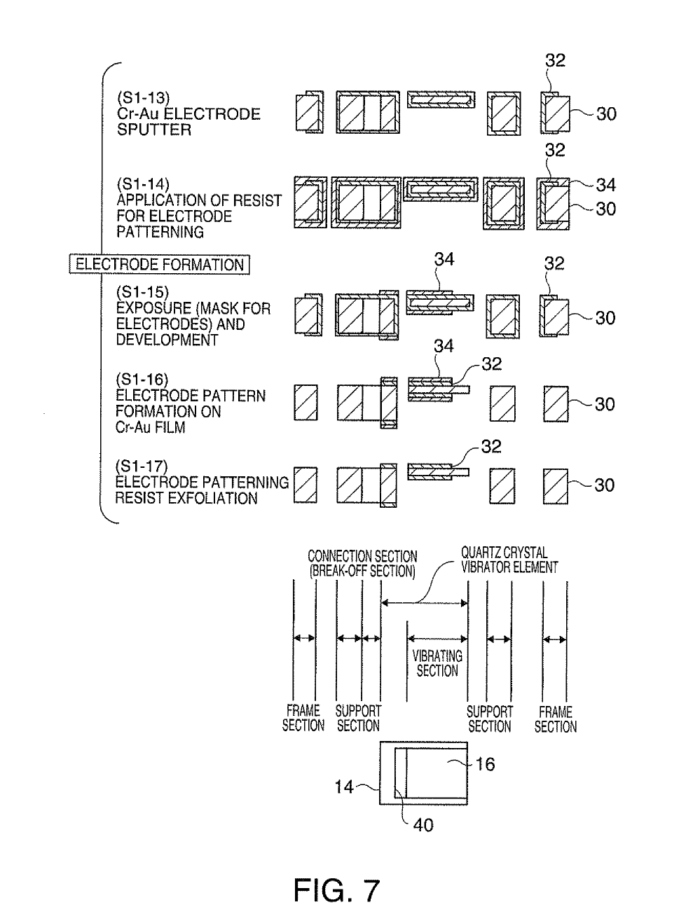

Subsequently, the electrode formation process shown in FIG. 7 is performed.

In this process, firstly, the Cr—Au film 32 for the electrodes is formed (S1-13) by sputtering. Then, a photoresist 34 for electrode patterning is applied (S1-14) to the surface of the Cr—Au film 32. Subsequently, the photoresist 34 is exposed using the photo mask for the electrode patterning, and then the development is performed to thereby remove (S1-15) the portions thus exposed.

Then the portions of the Cr—Au film 32 exposed by removing the exposed portions of the photoresist 34 are exfoliated (S1-16). Thus, the electrode pattern is provided to the Cr—Au film 32.

Subsequently, the photoresist 34 for the electrode pattern formation is exfoliated (S1-17), thus terminating the electrode formation process.

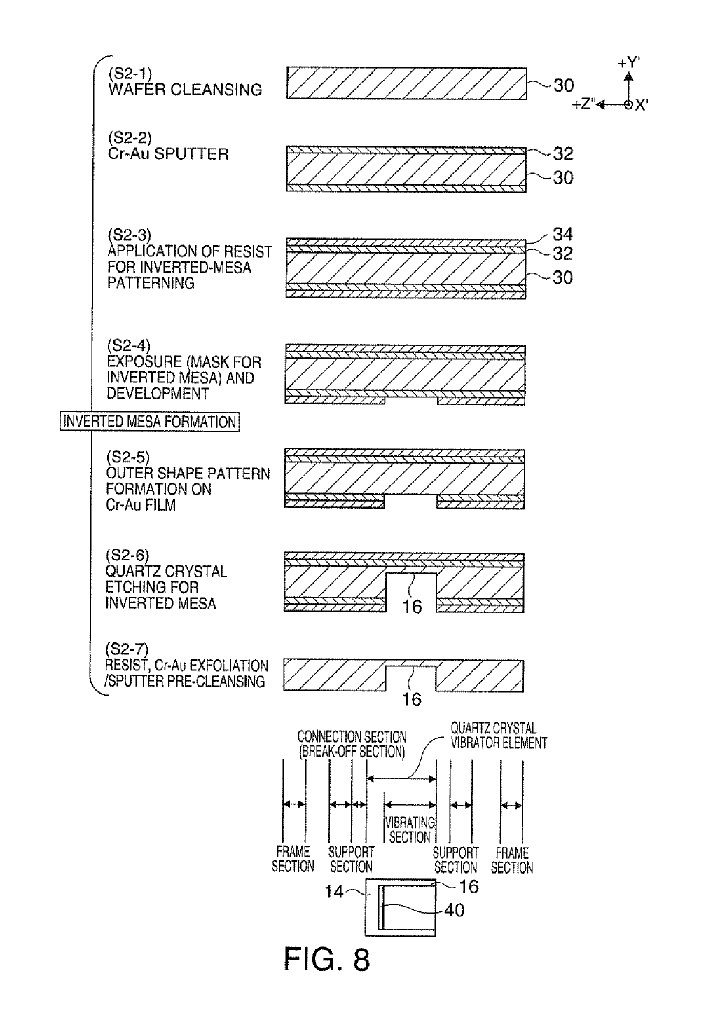

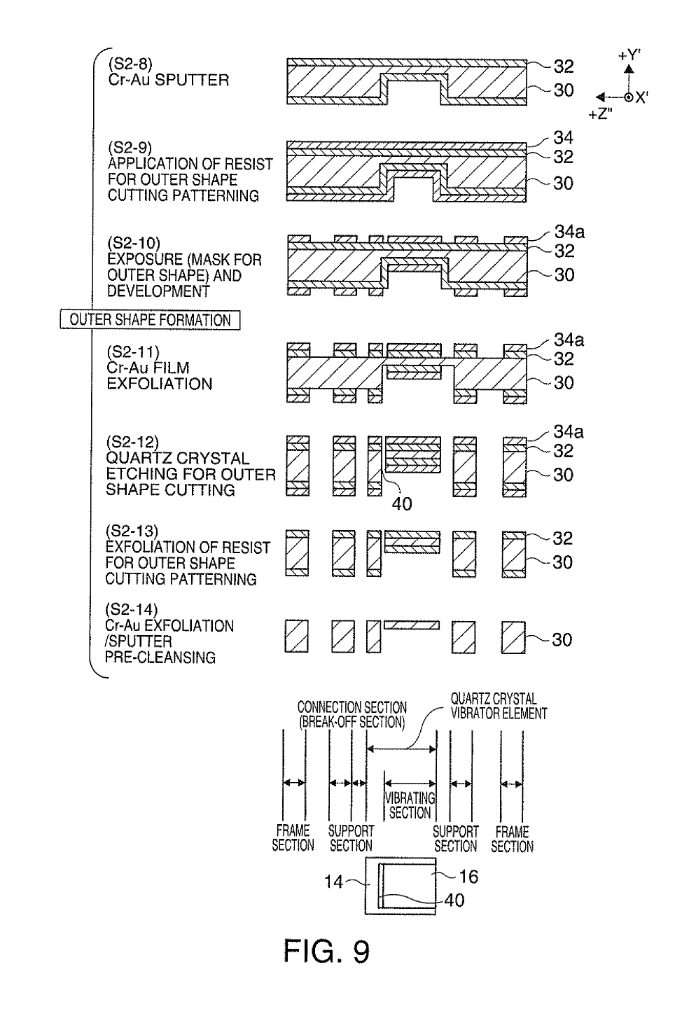

Then, the second manufacturing method of forming the outer shape of the quartz crystal vibrator element after forming the thin-wall section (the inverted mesa) will be explained with reference to FIGS. 8 and 9.

Firstly, an inverted mesa formation process shown in FIG. 8 is performed.

In the inverted mesa formation process, firstly the quartz crystal substrate 30 cut out in the AT-cut manner is cleaned (S2-1), then Cr—Au films 32 are formed (S2-2) on the both principal surfaces of the quartz crystal substrate 30 by sputtering. Then, a photoresist 34 is applied (S2-3) to the surface of each of the Cr—Au films 32.

Subsequently, the photoresist 34 in the area where the thin-wall section (the inverted mesa) is formed is exposed using the photo mask for forming the thin-wall section (the inverted mesa). Then, the development is performed to remove (S2-4) the portions thus exposed. Subsequently, by exfoliating the portion of the Cr—Au films 32 exposed by removing the photoresist 34, the outer shape pattern of the thin-wall section (inverted mesa) is provided (S2-5) to the Cr—Au films 32.

Subsequently, the wet etching on the portion of the quartz crystal substrate 30 thus exposed is performed using the photoresist 34 and the Cr—Au film 32 as the protective film to thereby form (S2-6) the thin-wall section 16 (inverted mesa). Subsequently, the photoresist and the Cr—Au film 32 are exfoliated, and then the cleansing is performed (S2-7).

Subsequently, the outer shape formation process shown in FIG. 9 is performed.

In the outer shape formation process, firstly, the Cr—Au films 32 are formed (S2-8) by sputtering on the both principal surfaces of the quartz crystal substrate 30, and then the photoresist 34 for outer shape cutting patterning is applied thereon (S2-9).

Subsequently, the photoresist 34 is exposed using a photo mask for the outer shape formation, and then the exposed portions are removed by the development, thereby forming (S2-10) the resist mask 34a. On this occasion, the outer shape of the quartz crystal vibrator element is formed so that the edges thereof are parallel to the Z″-axis and the X′-axis, respectively. Further, the outer shape of the slit section is formed in the area intervening between the thin-wall section and the thick-wall section shifted toward the +Z″ direction. Further, the resist masks 34a corresponding to the slit section 40 are disposed so that the positions of the masks of the both principal surfaces corresponding to each other are shifted from each other similar to the case of the first manufacturing process described above.

Subsequently, by exfoliating the portion of the Cr—Au films 32 exposed from the resist masks 34a, the outer shape pattern is provided (S2-11) to the Cr—Au films 32.

Subsequently, the wet etching is performed on the quartz crystal substrate 30 from the both principal surface sides using the resist masks 34a and the Cr—Au films 32 as the protective films, and the portion of the quartz crystal substrate 30 not protected is penetrated, thereby performing the outer shape cutting (S2-12).

Subsequently, the resist masks 34a are exfoliated (S2-13), then the Cr—Au films 32 are exfoliated, and then the quartz crystal substrate 30 is cleaned (S2-14).

Subsequently, the electrode formation process is performed to thereby form the electrode pattern. The electrode formation process is substantially the same as the electrode formation process in the first manufacturing method explained with reference to FIG. 7, and therefore, redundant explanation will be omitted.

In the first and second manufacturing methods of the quartz crystal vibrator element, the in-plane rotational angle (the angle of rotation of the +Z′-axis toward the +X-axis direction around the Y′-axis of the AT-cut quartz crystal plate to obtain the Z″-axis) ψ is set to −30°±5°, the edges of the quartz crystal vibrator element are arranged to be parallel to the Z″-axis and the X′-axis, respectively, and the thin-wall section is formed by the wet etching from the −Y′-axis side principal surface. Therefore, since the area (i.e., the area where the tilted surface appears with a large area and a large tilt angle) where a large residual dross appears due to the wet etching in the area intervening between the thin-wall section and the thick-wall section is the area shifted toward the +Z″ direction, the slit section 40 is formed in that area to thereby form the quartz crystal vibrator element with the small residual dross.

As described above, by making the area where the residual dross occurs and the area provided with the slit section 40 the same area, the necessity of assuring both of the area where the slit section 40 is formed and the area where the residual dross occurs when forming the outer shape is eliminated. Therefore, it is possible to miniaturize the quartz crystal vibrator element, and it is possible to increase the number of quartz crystal vibrator elements obtained from one wafer. Further, since the process for removing the residual dross can be reduced, the productivity can be improved.

It should be noted that in the case of forming the thin-wall section from the +Y′-axis side principal surface, the large residual dross is formed in the area intervening between the thin-wall section 16 shifted toward the −Z″ direction and the thick-wall section 14 adjacent thereto. Therefore, in the case in which the area is in the outer shape of the quartz crystal vibrator element, it is preferable to form the slit 40 at that area.

Further, although in the embodiment described above the in-plane rotational angle ψ is set to −30°±5°, this angle is not a limitation. In the case of performing the wet etching from the −Y′-axis side principal surface, the rotational angle with which the residual dross appears relatively significantly in the area shifted toward the +Z″ direction is in a range from −120° to 60°, and therefore, it is also possible to set the rotational angle in this range to the in-plane rotational angle ψ.

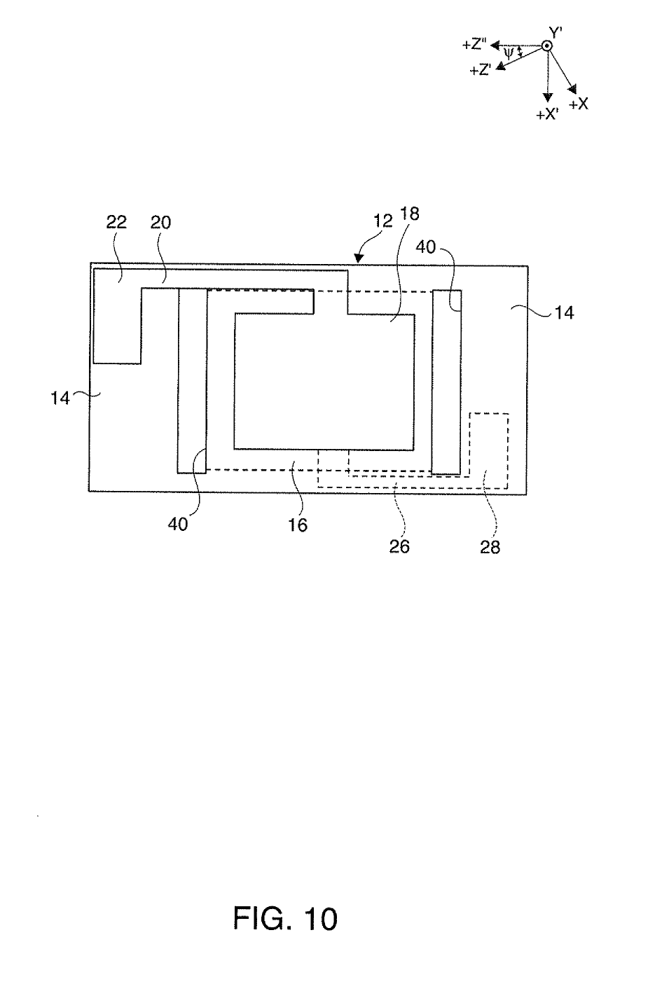

Further, a plurality of slit sections 40 can be disposed along the Z″-axis. For example, as shown in FIG. 10, in the case of the quartz crystal substrate 12 having the thick-wall section 14 formed in the entire circumference of the thin-wall section 16, it is also possible to dispose the slit section 40 in the area intervening between the thin-wall section 16 shifted toward the −Z″ direction and the thick-wall section 14 in addition to the slit section 40 disposed in the area intervening between the thin-wall section 16 shifted toward the +Z″ direction and the thick-wall section 14. Further, if the obverse-side connection electrode 22 and the reverse-side connection electrode 28 are disposed on the thick-wall sections 14 in each of the +Z″ direction end and the −Z″ direction end, and each of the obverse-side connection electrode 22 and the reverse-side connection electrode 28 is fixed to the package with the electrically conductive adhesive or the like, the impact resistance can be improved.

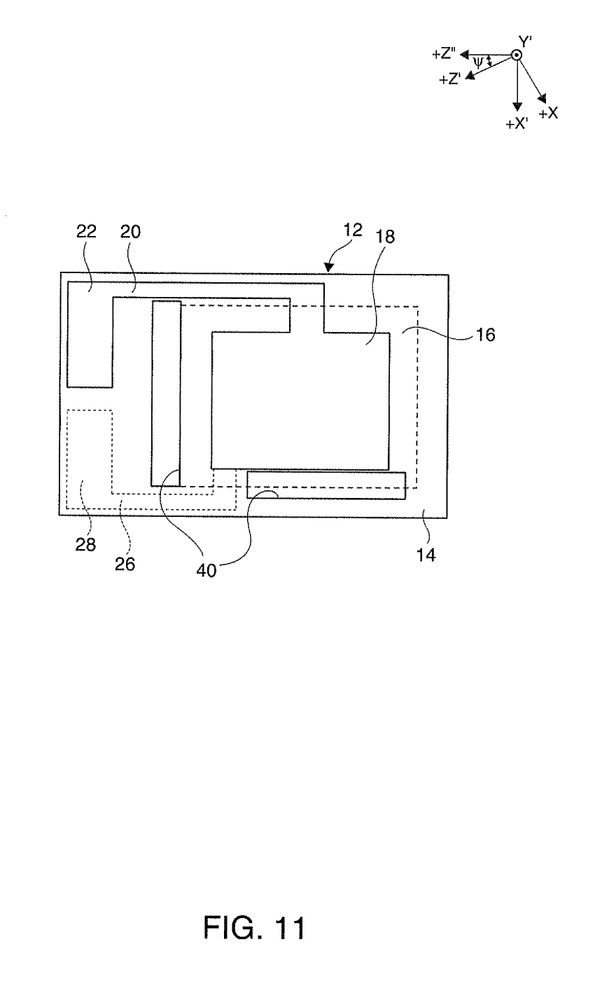

Further, even in the in-plane rotational angle ψ in a range from −120° to +60°, the difference is caused in the size of the residual dross appears in the area intervening between the thin-wall section 16 and the thick-wall section 14 in accordance with the in-plane rotational angle ψ. Therefore, by appropriately adjusting the area provided with the slit section 40 in accordance with the in-plane rotational angle ψ, the quartz crystal vibrator element with the small residual dross can be manufactured. For example, in the case in which the in-plane rotational angle ψ is in a range of −60° to −25°, and the wet etching for forming the thin-wall section 16 is performed from the −Y′-axis side principal surface, the residual dross is formed relatively significantly in the area shifted toward the direction in addition to the area shifted toward the +Z″ direction among the area intervening between the thin-wall section 16 and the thick-wall section 14. Therefore, it is preferable to dispose the slit sections 40 respectively in the area shifted toward the +Z″ direction and the area shifted toward the +X′ direction as shown in FIG. 11. On the other hand, in the case in which the wet etching for forming the thin-wall section 16 is performed from the +Y′-axis side principal surface in the in-plane rotational angle ψ in a range of −60° to −25°, the relatively large residual dross is formed in the area shifted toward the −X′ direction in addition to the area shifted toward the −Z″ direction among the area intervening between the thin-wall section 16 and the thick-wall section 14. Therefore, it is preferable to dispose the slit sections 40 respectively in the area shifted toward the −Z″ direction and the area shifted toward the −X′ direction.

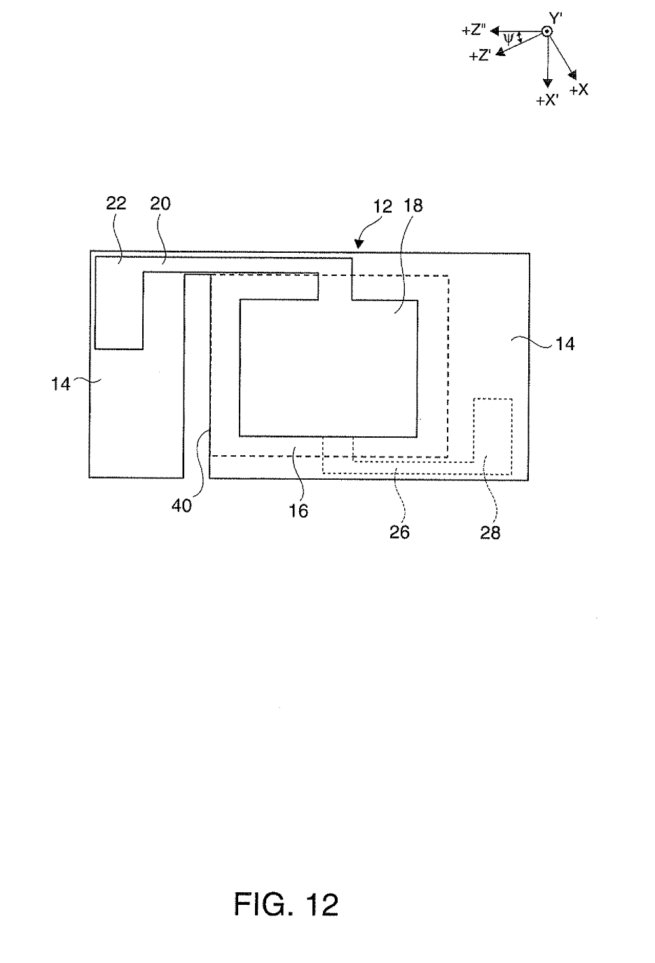

Further, in the case of disposing the slit section 40, for example, in the area intervening between the thin-wall section 16 and the thick-wall section 14 shifted toward the +Z″ direction, it is possible to dispose the slit section 40 in a part of the area. However, by disposing the slit section 40 in the entire area, the residual dross can further be reduced. Further, the shape of the slit section 40 is not limited to the rectangular top shape, but can be a circular shape, a V shape, an L shape, a T shape, and so on. Further as shown in FIG. 12, the slit section 40 can be formed by cutting the quartz crystal substrate 12 from a side surface. By adopting the shape of cutting from the side surface as the slit section 40, it is possible to make the stress from the thick-wall section 14 shifted toward the Z″ direction and fixed to the package with the electrically conductive adhesive difficult to propagate to the thin-wall section 16 as the vibrating section.

The quartz crystal vibrator element is mounted on the package to become the quartz crystal vibrator. As the method of mounting the quartz crystal vibrator element on the package, there can be cited a method of fixing the two places of the obverse-side connection electrode 22 and the reverse-side connection electrode 28 respectively to two mounting electrodes provided to the package via the electrically conductive adhesive.

Besides the method of fixing the two places of the quartz crystal vibrator element with the electrically conductive adhesive, there can also be cited a method of fixing the reverse-side connection electrode 28 alone to the mounting electrode of the package with the electrically conductive adhesive, and electrically connecting the obverse-side connection electrode 22 to the pad electrode of the package with a bonding wire.

The method of fixing one place alone with the electrically conductive adhesive can more preferably prevent the distortion from occurring at the fixed place during the reflow process for curing the electrically conductive adhesive to thereby prevent the harmful influence being exerted on the vibration compared to the method of fixing the two places with the electrically conductive adhesive.

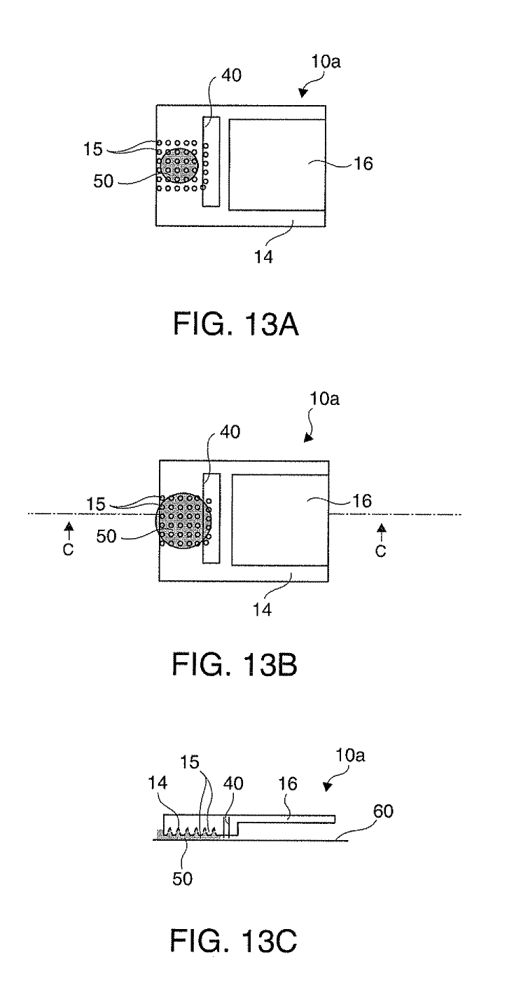

Further, in the case of fixing the quartz crystal vibrator element to the package with the electrically conductive adhesive, it is also possible to provide a plurality of grooves, which have the connection electrode formed on the surface, to the place to be coated with the electrically conductive adhesive of the quartz crystal vibrator element. FIGS. 13A through 13C are schematic diagrams for explaining the quartz crystal vibrator element 10a provided with the plurality of grooves. FIG. 13A is the schematic diagram showing the positional relationship between the quartz crystal vibrator element 10a and the electrically conductive adhesive 50 viewed from below before the quartz crystal vibrator element 10a is made to have contact with the electrically conductive adhesive 50 and then is fixed to the package, and FIG. 13B is a schematic diagram showing the condition of extension of the electrically conductive adhesive 50 in the horizontal direction when the quartz crystal vibrator element 10a and the package are fixed to each other with the electrically conductive adhesive 50, FIG. 13C is a schematic cross-sectional view of the quartz crystal vibrator element 10a shown in FIG. 13B along the line C-C.

As described above, by providing the plurality of grooves 15 to the place of the quartz crystal vibrator element 10a to be coated with the electrically conductive adhesive 50, the electrically conductive adhesive 50 can be prevented from widely extending in horizontal directions. Since the extension of the electrically conductive adhesive 50 is reduced, the quartz crystal vibrator element 10a becomes hard to be affected by the rotation and the twist. Further, the contact area between the electrically conductive adhesive 50 and the quartz crystal vibrator element 10a can be increased by the plurality of grooves 15, and thus, the bonding strength can be enhanced.

It should be noted that although the example of mounting the quartz crystal vibrator element 10a in the package 60 with the principal surface, which is provided with the recess (the inverted mesa) of the thin-wall section 16, put on the downside, it is also possible to mount it to the package 60 with the principal surface provided with the recess put on the upside.

Further, although in the embodiment described above the AT-cut quartz crystal substrate is used as the quartz crystal substrate 12, quartz crystal substrate with other cutting angles can be used providing the substrate causes the residual dross due to the wet etching, and piezoelectric ceramics can also be used.

The entire disclosure of Japanese Patent Application Nos: 2010-169010, filed Jul. 28, 2010 are expressly incorporated by reference herein.

What is claimed is:

1. A piezoelectric vibrator element provided by performing wet etching on a piezoelectric substrate, comprising:
a thin-wall section including a vibrating section;
a thick-wall section thicker than the thin-wall section; and
a slit section penetrating in a thickness direction,
wherein the slit section is disposed in an area intervening between the thin-wall section and the thick-wall section.

2. The piezoelectric vibrator element according to claim 1, wherein
at least a part of the thick-wall section is provided with a connection electrode to be connected to an electrode provided to a package,
the thin-wall section is provided with an excitation electrode electrically connected to the connection electrode, and
the slit section is disposed in the area, which intervenes between the thin-wall section and the thick-wall section, and is sandwiched between the connection electrode and the excitation electrode.

3. The piezoelectric vibrator element according to claim 2, wherein
portions of the thick-wall section adjacent to both sides of the thin-wall section are each provided with the connection electrode, and
the slit section is disposed in an area intervening between each of the thick-wall sections provided with the connection electrode and the thin-wall section.

4. The piezoelectric vibrator element according to claim 1, wherein
the piezoelectric substrate is an AT-cut substrate,
the piezoelectric substrate has edges respectively parallel to a Z″-axis obtained by rotating a Z′-axis in the piezoelectric substrate around a Y′-axis, and an X′-axis perpendicular to the Z″-axis, and
the slit section is disposed on one end side of the Z″-axis direction.

5. The piezoelectric vibrator element according to claim 1, wherein
the piezoelectric substrate is an AT-cut substrate,
the piezoelectric substrate has edges respectively parallel to a Z″-axis obtained by rotating a Z′-axis in the piezoelectric substrate around a Y′-axis, and an X′-axis perpendicular to the Z″-axis, and
a plural number of the slit sections are disposed along the Z″-axis.

6. The piezoelectric vibrator element according to claim 1, wherein
the piezoelectric substrate is an AT-cut substrate,
the piezoelectric substrate has edges respectively parallel to a Z″-axis obtained by rotating a Z′-axis in the piezoelectric substrate around a Y′-axis, and an X′-axis perpendicular to the Z″-axis, and
the slit section is disposed in parallel to the Z″-axis.

7. The piezoelectric vibrator element according to claim 1, wherein
assuming that an angle of rotation of a +Z′-axis around a Y′-axis toward the +X-axis direction corresponds to a positive rotational angle in the piezoelectric substrate, the piezoelectric substrate has edges respectively parallel to a Z″-axis obtained by rotating a Z′-axis around a Y′-axis in a range from −120° to +60°, and an X′-axis perpendicular to the Z″-axis, and
the thin-wall section is formed by wet etching from either one of a +Y′-axis side principal surface and a −Y′-axis side principal surface, and is provided with the slit section disposed at least in the area at a position shifted toward a −Z″ direction if the wet etching is performed from the +Y′-axis side principal surface, and is provided with the slit section disposed at least in the area at a position shifted toward a +Z″ direction if the wet etching is performed from the −Y′-axis side principal surface.

8. The piezoelectric vibrator element according to claim 7, wherein
the range of the rotational angle of the Z′-axis is set to a range from −60° to −25°, and
the slit sections are disposed at least in the area at positions respectively shifted toward the −Z″ direction and the −X′ direction if the wet etching is performed from the +Y′-axis side principal surface, and the slit sections are disposed at least in the area at positions respectively shifted toward the +Z″ direction and the +X′ direction if the wet etching is performed from the −Y′-axis side principal surface.

9. The piezoelectric vibrator element according to claim 1, wherein
the slit section is formed by cutting a side surface.

10. A method of manufacturing a piezoelectric vibrator element having a thin-wall section including a vibrating section, a thick-wall section thicker than the thin-wall section, and a slit section penetrating in a thickness direction, the method comprising:
forming an inverted-mesa shape by forming the thin-wall section and the thick-wall section by wet etching to one of principal surfaces of a piezoelectric substrate; and
forming the slit section in an area intervening between the thin-wall section and the thick-wall section.

11. The method of manufacturing a piezoelectric vibrator element according to claim 10, wherein
the slit section is formed at least in an area with a tilt surface having a largest tilt angle out of an area intervening between the thin-wall section and the thick-wall section.

12. The method of manufacturing a piezoelectric vibrator element according to claim 10, wherein
wet etching is performed on both principal surfaces of the piezoelectric substrate in a condition in which masks corresponding to an outer shape of the slit section are disposed so as to be shifted from each other in a principal surface direction of the piezoelectric substrate.
